(19) United States
(12) Patent Application Publication
(10) Pub. No.: US 2026/0033051 A1
(43) Pub. Date: Jan. 29, 2026

(54) LIGHTING DEVICE FOR A MOTOR VEHICLE

(71) Applicant: VALEO VISION, Bobigny (FR)

(72) Inventors: Sid Ahmed BEDDAR, Bobigny (FR); Alexandre CORMAN, Bobigny (FR); Stephane ANDRE, Bobigny (FR)

(73) Assignee: VALEO VISION, Bobigny (FR)

(21) Appl. No.: 18/994,846

(22) PCT Filed: Jul. 18, 2023
(86) PCT No.: PCT/EP2023/069967

§ 371 Date: Jan. 15, 2025

(30) Foreign Application Priority Data
Jul. 20, 2022 (FR) FR2207421

(51) Int. Cl. H10H 20/855; B60K 35/22; H10H 20/85; H10H 20/853

(52) U.S. Cl. CPC H10H 20/855; H10H 20/8508; H10H 20/853; B60K 35/22; B60K 2360/1523; B60K 2360/332

(57) ABSTRACT

A luminous device including an optical device and a first printed circuit board on which is fastened a light source including a light ray emitting zone and a protective housing surrounding the light ray emitting zone. A first height of the protective housing, relative to a flat surface of the first printed circuit board, being greater than a second height of the light ray emitting zone. The luminous device also includes a mask arranged between the optical device and the light ray emitting zone so as to prevent rays coming from the light ray emitting zone from being reflected on the protective housing and reaching the optical device, the mask bearing directly against the first printed circuit board and/or directly against the light source.

### TECHNICAL FIELD

The invention relates to a luminous device for an automotive vehicle.

### BACKGROUND OF THE INVENTION

Nowadays, automotive vehicle optical systems comprise ultra-pixelated LED type light sources that make it possible to display varied images. However, the use of such a light source in a vehicle optical system requires various problems to be solved.

First of all, the sharpness of the images projected by the light source may be adversely affected by phenomena of reflection of the rays coming from the light ray emitting zone on elements situated in the optical system and close to the light ray emitting zone. In particular, light reflections can be caused by a reflective surface of a protective housing, said reflective surface overhanging the light ray emitting zone of the light source.

Furthermore, the operation of the light source may be disturbed by external electromagnetic fields generated by electronic components situated near the light source.

In addition, the light source produces heat that it is necessary to evacuate in order not to the damage the electronic components situated in the light source or near the light source.

In addition, it is necessary to protect the components of the optical system against the destructive nature of the solar rays penetrating via the lens of the optical system.

### SUMMARY OF THE INVENTION

The object of the invention is to provide a luminous device that makes it possible to overcome the constraints described above. In particular, the invention makes it possible to produce a luminous device that is simple and reliable and that simultaneously makes it possible to filter light reflections on a protective housing bordering the light ray emitting zone of the luminous device, to protect the luminous device from the solar rays and the surrounding electromagnetic fields, and to dissipate the heat produced by the light ray emitting zone.

To this end, the invention relates to a luminous device comprising an optical device and a first printed circuit board on which is fastened a light source comprising a light ray emitting zone and a protective housing surrounding the light ray emitting zone, a first height of the protective housing relative to a flat surface of the first printed circuit board, measured in a first direction directed toward the optical device perpendicular to said flat surface, being greater than a second height of the light ray emitting zone relative to the flat surface measured in the first direction,
the luminous device comprising a mask arranged between the optical device and the light ray emitting zone so as to prevent rays coming from the light ray emitting zone from being reflected on the protective housing and reaching the optical device,
the mask bearing directly against the first printed circuit board and/or directly against the light source.

In one embodiment, the mask bears directly against the light ray emitting zone and/or against the protective housing of the light source.

In one embodiment, the mask extends along a main surface and comprises an opening delimited by inner edges for the passage of light rays produced by the light ray emitting zone, the inner edges projecting from the main surface, or being in the continuation of the main surface.

In one embodiment, the ends of the inner edges of the mask have a chamfer, for example a chamfer of 45 degrees, oriented toward the light ray emitting zone.

In one embodiment, the inner edges of the mask project from the main surface of the mask, and the ends of the inner edges bear directly against the light ray emitting zone, so as to border the periphery of the light ray emitting zone.

In one embodiment, the mask bears directly against a heat sink disposed close to the luminous device, so as to promote the cooling of the light ray emitting zone.

In one embodiment, the mask is made from a flexible material allowing the inner edges to match the shape of the light ray emitting zone.

In one embodiment, the inner edges of the mask are in the continuation of the main surface of the mask, and a portion of the main surface of the mask bears directly against the protective housing.

In one embodiment, the mask is made of metal, in particular of aluminum, or of stainless steel.

In one embodiment, the mask forms a Faraday cage inside which the light source is placed.

### BRIEF DESCRIPTION OF DRAWINGS

The appended drawings show, by way of example, an embodiment of a luminous device according to the invention.

FIG. 1 schematically shows an embodiment of a luminous device according to the invention

FIG. 2 schematically shows a view in cross section of a printed circuit board on which a light ray emitting zone and a protective housing are fastened.

FIG. 3 illustrates an embodiment of a light source.

FIG. 4 shows a top view of a first embodiment of a luminous device according to the invention.

FIG. 5 shows a view in cross section of the first embodiment of a luminous device according to the invention.

FIG. 6 shows a view in cross section of a second embodiment of a luminous device according to the invention.

FIG. 7 shows a view in cross section of a third embodiment of a luminous device according to the invention.

### DETAILED DESCRIPTION OF THE INVENTION

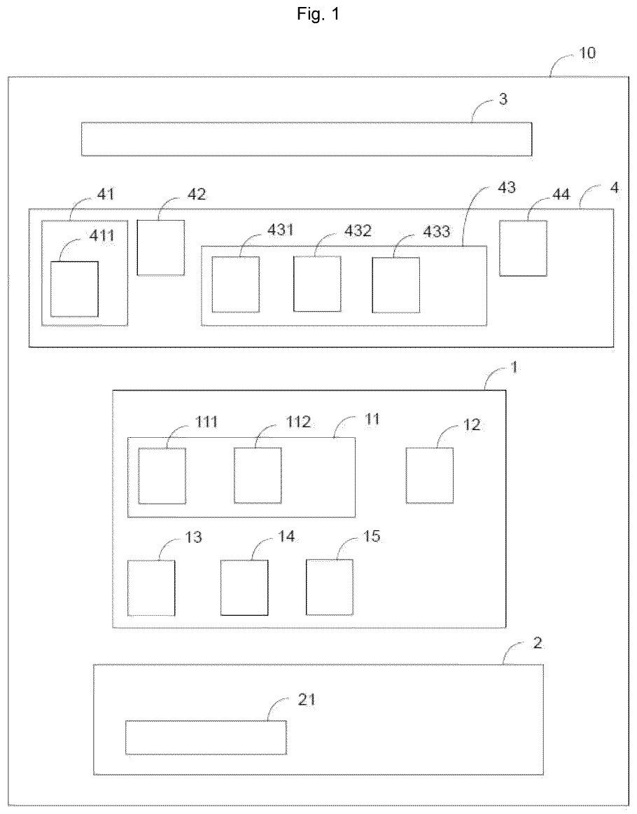

A first embodiment of a luminous device according to the invention is shown by FIG. 1.

The luminous device 10 mainly comprises,
a light source 1 comprising a light ray emitting zone 11, and a protective housing 12 surrounding the light ray emitting zone 11,
a first printed circuit board 2 having a surface 21 on which the light ray emitting zone 11 and the protective housing 12 are fastened,
an optical device 3, which may for example be a lens, and
a mask 4 disposed between the light ray emitting zone 11 and the optical device 3.

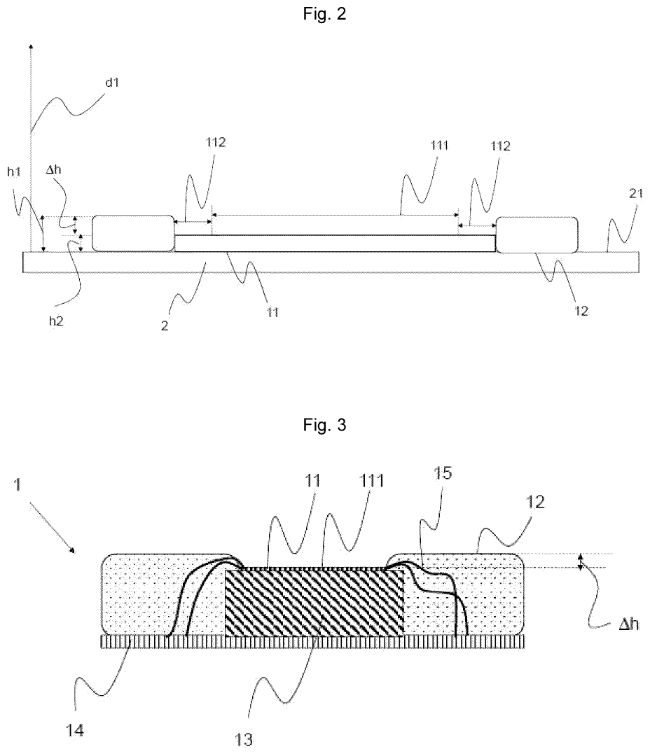

Preferentially, the light source 1 is an LED, the structure of which is detailed by FIGS. 2 and 3.

FIG. 2 provides a first schematic depiction of the light ray emitting zone 11 surrounded by the protective resin 12.

The light ray emitting zone 11 is divided into a first zone 111 referred to as active zone comprising photon-emitting matter, and a second zone 112 referred to as technical zone not comprising photon-emitting matter.

The active zone 111 comprises physical matter that emits photons when an electric current passes through it, thus generating blue light. The active zone 111 also comprises a phosphor layer that transforms blue light into white light.

The active zone 111 is also called a “matrix of pixels”. The photon-emitting matter is divided into pixels. Each pixel can be controlled individually to emit photons. Each pixel of the matrix 111 is able to emit light rays over 180 degrees. In one embodiment, the matrix of pixels 111 may comprise 25000 pixels.

The technical zone 112 is situated at the periphery of the active zone 111. In other words, the technical zone 112 is a thin strip that borders the periphery of the active zone 111 and that does not emit any light. The order of magnitude of the width of the technical zone 112 is 500 microns, or even 300 microns.

In a preferred embodiment, the protective housing 12 is a protective resin 12 molded around the technical zone 112.

In the remainder of the document, the terms “protective housing” and “protective resin” are used interchangeably.

The light ray emitting zone 11 and the protective resin 12 are fastened on a flat surface 21 of the first printed circuit board 2.

A first direction d1 is defined, perpendicular to the flat surface 21 of the first printed circuit board 2, the direction d1 being oriented toward the optical device 3.

In the embodiment described, a first height h1 of the protective resin 12 relative to the flat surface 21, measured in the first direction d1, is greater than a second height h2 of the light ray emitting zone 11 relative to the flat surface 21, measured in the first direction d1. In other words, the height h1 of the protective resin 12 exceeds the height h2 of the light ray emitting zone 11. For example, the height h1 is greater than the height h2, the difference Ah between the two heights being able to be, for example, 0.2 to 0.3 mm.

FIG. 3 schematically shows the light source 1, or LED 1, comprising the light ray emitting zone 11 and the protective resin 12 that are described above. In this more detailed view, the structure of the LED 1 appears more precisely. In particular, the matrix of pixels 111 is shown associated with a matrix of switches 13.

The LED 1 also comprises a second printed circuit board 14 intended to control the matrix of switches 13. The assembly constituted by the matrix of pixels 111 and the matrix of switches 13 is fastened on the second printed circuit board 14, for example by soldering.

The second printed circuit board 14 makes it possible to independently control the state of each pixel of the LED 1 as being illuminated or switched off. A network of wired connections 15 makes it possible to control each of the pixels. The wired connections 15 are disposed between the emitting surface 11 and the second printed circuit board 14.

The protective resin 12 has the role of protecting the network of wired connections 15. To this end, the protective resin 12 completely envelops the network of wired connections 15. Thus, the height difference Ah between the emitting surface 11 and the protective resin 12 is due to the volume occupied by the network of wired connections 15 and to the surplus thickness of resin necessary to envelope the ends of the wired connections 15 that are connected to the emitting surface 11.

In addition, for better thermal insulation of the network of wired connections, the protective resin is preferentially light in color, in order not to absorb the heat.

The overthickness of the protective resin 12, and its ability to reflect the light contribute to generating parasitic light reflections in the LED 1.

In order to neutralize the parasitic light reflections, the luminous device 10 comprises a mask 4 arranged between the optical device 3 and the light ray emitting zone 11. The mask 4 has the role of preventing rays coming from the light ray emitting zone 11, and being reflected on the protective resin 12, from reaching the optical device 3.

In other words, a mask 4 has been integrated into the luminous device 10, so as to block light reflections—which are generated by the overthickness Ah of the protective resin 12 relative to the emitting zone 11—before they reach the optical device 3.

In the absence of a mask 4, the emitting zone 11 bordered by the protective resin 12 defines a first light beam 20, shown in FIGS. 5 to 7. The first light beam 20 corresponds to the rays emitted by the emitting zone 11 reaching the optical device 3 without reflection on the protective resin 12.

The mask 4 with which the luminous device 10 is equipped extends along a main surface 41 and comprises an opening 42 delimited by inner edges 43, the opening 42 allowing the passage, toward the optical device 3, of light rays produced by the light ray emitting zone 11.

In the presence of the mask 4, the emitting zone 11 then defines a second light beam 30, which corresponds to the rays emitted by the emitting zone 11 reaching the optical device 3 after having passed through the mask 4. Depending on the shape of the opening 42, the light beam 20 may take various shapes, for example a conical shape if the opening 42 is circular.

Advantageously, the shape of the opening 42 is defined such that the second light beam 30 is substantially identical to the first light beam 20, and so as to filter light rays resulting from reflection on the protective resin 12.

The ends 431 of the inner edges 43 of the mask have a chamfer 432, for example a chamfer of 45 degrees, oriented toward the light ray emitting zone 11. The chamfer has the effect of preventing the reflection of light rays, coming from the emitting zone 11, on the ends 431 of the inner edges 43.

The main surface 41 is preferentially parallel to the surface of the light ray emitting zone 11.

Advantageously, the mask 4 is made from a light-absorbing material, in particular the mask 4 is made from a dark material. This feature of the mask 4 has the first effect of preventing the reflection of rays coming from the emitting zone 11 on the mask 4. It also has the effect of protecting the luminous device 10 against the destructive effect of solar rays penetrating into the luminous device 10 via the optical device 3.

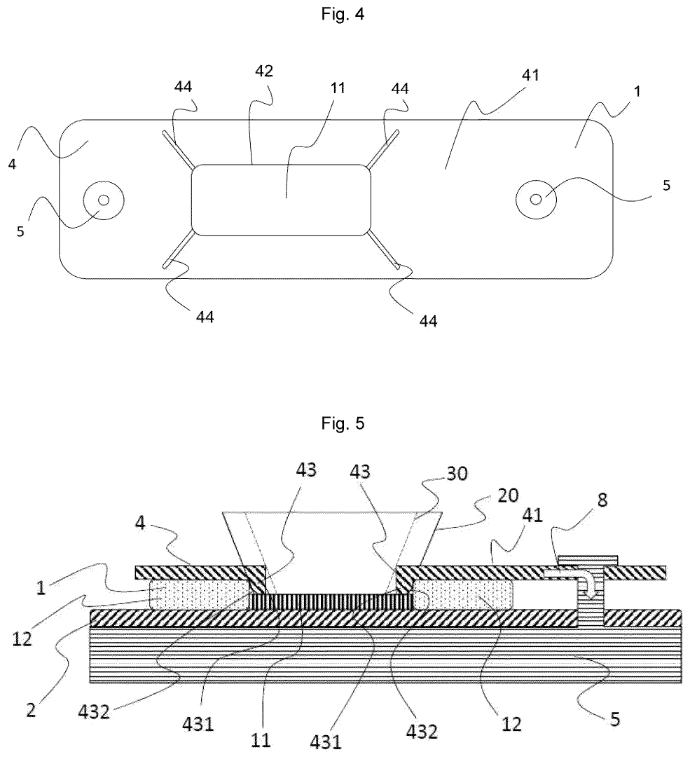

Various embodiments of the mask 4 are described below with reference to FIGS. 4 to 7. Depending on the embodiment, the mask 4 bears directly against the first printed circuit board 2 and/or directly against the light source 1. In the case in which it bears against the light source 1, the mask 4 may bear directly against the light ray emitting zone 11 and/or against the protective housing 12.

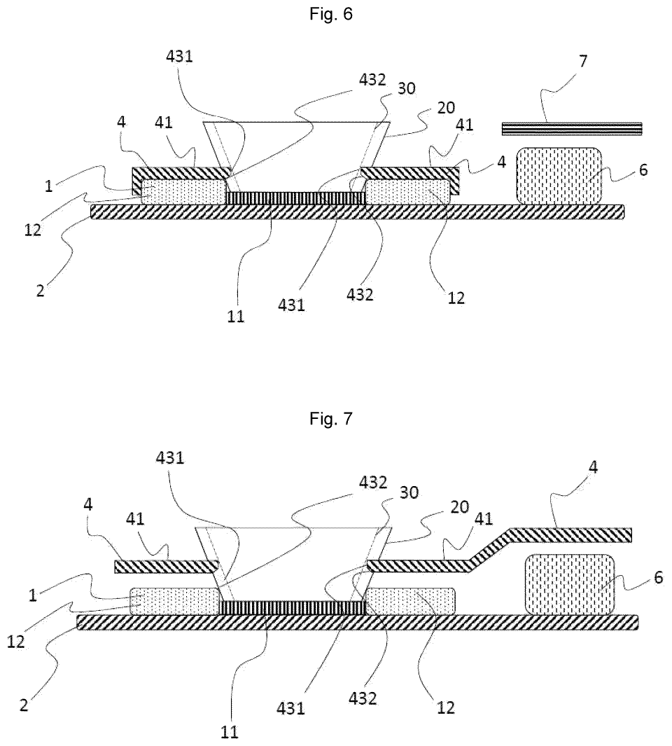

Thus,
in the first embodiment, described by FIGS. 4 and 5, the mask 4 bears against the emitting surface 11, which forms part of the LED 1, the LED 1 itself being fastened to the first printed circuit board 2,
in the second embodiment, described by FIG. 6, the mask 4 bears against the protective resin 12, which forms part of the LED 1, the LED 1 itself being fastened to the first printed circuit board 2, and
in the third embodiment, described by FIG. 7, the mask 4 bears against the first printed circuit board 2.

In the first embodiment, the inner edges 43 of the mask 4 project from the main surface 41; in the second and third embodiments, the inner edges 43 of the mask 4 are in the continuation of the main surface 41.

FIGS. 4 and 5 respectively schematically show a view from above and a view in cross section of the first embodiment of the luminous device 10 according to the invention.

In the first embodiment, the inner edges 43 of the mask 4 are substantially perpendicular to the main surface 41 of the mask 4, and oriented toward the light ray emitting zone 11. The ends 431 of the inner edges 43 are in contact with the light ray emitting zone 11, so as to border the periphery of the light ray emitting zone 11. Advantageously, contact between the ends 431 and the light ray emitting zone 11 is made close to the technical zone 112 of the light ray emitting zone 11.

Advantageously, in the first embodiment, the chamfer 432 is oriented facing both the light ray emitting zone 11 and the protective resin 12.

Advantageously, the mask 4 is made from a flexible material allowing the inner edges 43 to match the shape of the light ray emitting zone 11, in particular allowing the ends 431 of the inner edges 43 to come into contact with the emitting zone 11 while at the same time being as close as possible to the technical zone 112. In addition, the mask 4 may have cutouts 44 making it easier to adjust the inner edges 43 to the shape of the light ray emitting zone 11. The adjustment of the inner edges 43 to the shape of the emitting zone may require an overlap at the borders of the cutouts 44: in this case, at at least one cutout 44, a first border of the cutout overlaps a second border of the cutout.

In the second embodiment, shown by FIG. 6, the inner edges 43 of the mask 4 are in the continuation of the main surface 41 of the mask 4, and a portion 411 of the main surface of the mask bears directly against the protective resin 12. As a result of their shape and of their material absorbing the rays, the inner edges of the mask 4, in particular as a result of the ends 431 and the chamfer 432, block the rays coming from the emitting zone 11 that are reflected on the protective resin 12.

In the third embodiment, shown by FIG. 7, the inner edges 43 of the mask 4 are in the continuation of the main surface 41 of the mask 4, and the mask 4 bears directly against the first printed circuit board 2 (the connection between the mask 4 and the first printed circuit board 2 is not shown in FIG. 7). As in the second embodiment, as a result of their shape and of their material absorbing the rays, the inner edges of the mask 4, in particular as a result of the ends 431 and the chamfer 432, block the rays coming from the emitting zone 11 that are reflected on the protective resin 12.

Depending on the embodiment, in particular in the third embodiment, the mask 4 may also serve to protect electronic components 6 situated close to the optical device 10 and not forming part of the optical device 4 from solar rays. By contrast, in the second embodiment, the mask 4 will not be able to fulfill this function and an additional solar protection device 7 will be necessary to protect electronic components 6 disposed near the LED 1.

In certain embodiments, in particular in the first embodiment of the luminous device 10, the mask 4 is connected to a heat sink 5 disposed close to the luminous device 10, so as to promote the cooling of the light ray emitting zone 11, via a thermal path 8. In order to promote the thermal evacuation of the heat coming from the emitting zone 11, the mask 4 must have a minimal thickness, the minimal thickness being able to depend on the material constituting the mask 4.

Advantageously, the mask 4 can form a Faraday cage inside which the light source 1 (or LED 1) is placed, limiting the passage of the surrounding electromagnetic waves in the direction of the light source 1. In one embodiment, the Faraday cage formed by the mask 4 also protects equipment surrounding the LED 1 from the electromagnetic emissions coming from the LED 1.

Finally, the luminous device according to the invention makes it possible to overcome the various problems encountered during the use of an LED type light source in an automotive vehicle optical system, and more specifically when the protective housing of the LED generates light reflections that are liable to disturb the image projected by the luminous device.

Placed as close as possible to the light source, the mask according to the invention makes it possible to eliminate the reflected rays while at the same time retaining a useful light beam substantially equivalent to the useful beam that would be obtained without a mask.

In one embodiment, the mask according to the invention is in contact with the light ray emitting zone of the LED and thus allows the heat generated by the LED to be evacuated via a thermal path connecting the mask to a heat sink.

Advantageously, the mask according to the invention also protects the LED-and electronic components surrounding the LED-against the solar rays liable to penetrate via the lens of the luminous device, and also against electromagnetic radiation.

What is claimed is:

1. A luminous device comprising an optical device and a first printed circuit board on which is fastened a light source including a light ray emitting zone and a protective housing surrounding the light ray emitting zone, a first height of the protective housing relative to a flat surface of the first printed circuit board, measured in a first direction directed toward the optical device perpendicular to the flat surface, being greater than a second height of the light ray emitting zone relative to the flat surface measured in the first direction, wherein the luminous device also includes a mask arranged between the optical device and the light ray emitting zone so as to prevent rays coming from the light ray emitting zone from being reflected on the protective housing and reaching the optical device, the mask bearing directly against the first printed circuit board and directly against the light source.

2. The luminous device as claimed in claim 1, wherein the mask bears directly against the light ray emitting zone and against the protective housing of the light source.

3. The luminous device as claimed in claim 1, wherein the mask extends along a main surface and includes an opening delimited by inner edges for the passage of light rays produced by the light ray emitting zone, the inner edges projecting from the main surface.

4. The luminous device as claimed in claim 3, wherein the ends of the inner edges of the mask have a chamfer, for example a oriented toward the light ray emitting zone.

5. The luminous device as claimed in claim 3, wherein the ends of the inner edges bear directly against the light ray emitting zone, so as to border the periphery of the light ray emitting zone.

6. The luminous device as claimed in claim 5, wherein the mask bears directly against a heat sink disposed close to the luminous device, so as to promote the cooling of the light ray emitting zone.

7. The luminous device as claimed in claim 5, wherein the mask is made from a flexible material allowing the inner edges to match the shape of the light ray emitting zone.

8. The luminous device as claimed in claim 12, wherein a portion of the main surface of the mask bears directly against the protective housing.

9. The luminous device as claimed in claim 1, wherein the mask is made of metal.

10. The luminous device as claimed in claim 1, wherein the mask forms a Faraday cage inside which the light source is located.

11. The luminous device as claimed in claim 1, wherein the mask bears directly against the light ray emitting zone or against the protective housing of the light source.

12. The luminous device as claimed in claim 1, wherein the mask extends along a main surface and includes an opening delimited by inner edges for the passage of light rays produced by the light ray emitting zone, the inner edges being in a continuation of the main surface.

13. The luminous device as claimed in claim 4, wherein the chamfer is of 45 degrees.

14. The luminous device as claimed in claim 12, wherein ends of the inner edges of the mask have a chamfer oriented toward the light ray emitting zone.

15. The luminous device as claimed in claim 14, wherein the chamfer is of 45 degrees.

16. The luminous device as claimed in claim 1, wherein the mask is made of aluminium.

17. The luminous device as claimed in claim 1, wherein the mask is made of stainless steel.

18. A luminous device comprising an optical device and a first printed circuit board on which is fastened a light source including a light ray emitting zone and a protective housing surrounding the light ray emitting zone, a first height of the protective housing relative to a flat surface of the first printed circuit board, measured in a first direction directed toward the optical device perpendicular to the flat surface, being greater than a second height of the light ray emitting zone relative to the flat surface measured in the first direction, wherein the luminous device also includes a mask arranged between the optical device and the light ray emitting zone so as to prevent rays coming from the light ray emitting zone from being reflected on the protective housing and reaching the optical device, the mask bearing directly against the first printed circuit board or directly against the light source.
